(19) United States
(12) Patent Application Publication
(10) Pub. No.: US 2010/0116318 A1
(43) Pub. Date: May 13, 2010

(54) PIXELATED PHOTOVOLTAIC ARRAY METHOD AND APPARATUS

(75) Inventors: David S. Sumida, Los Angeles, CA (US); Dennis C. Jones, Malibu, CA (US); Hans W. Bruesselbach, Calabasas, CA (US); Authi A. Narayanan, Thousand Oaks, CA (US)

Correspondence Address: O'Connor & Company, P.O. Box 7389, Broomfield, CO, 80021-0024, US

(73) Assignee: HRL LABORATORIES, LLC, Malibu, CA (US)

(21) Appl. No.: 11/683,434

(22) Filed: Mar. 8, 2007

(51) Int. Cl. H01L 31/052

(52) U.S. Cl. 136/246

(57) ABSTRACT

The present invention comprises a method and apparatus to increase the efficiency of photovoltaic conversion of light into electrical power and to achieve operation at higher optical power and therefore higher electrical power. Preferred embodiments increase the efficiency of photovoltaic power conversion of any source of a beam of photons by spatially dividing the beams into a plurality of individual beamlets, each beamlet focusing on an active photovoltaic region. The preferred architecture of the apparatus of the invention comprises spatially separated photovoltaic cells to substantially match the pattern of the spatially separated plurality of beamlets. Preferred embodiments result in a significant reduction in ohmic losses and current shunting, thereby increasing photovoltaic conversion efficiencies.

### FIELD OF THE INVENTION

The present invention relates to conversion of photons, such as from a laser or light source, into electrical energy using photovoltaic cells. The present invention specifically relates to an apparatus and methods to increase the efficiency of energy conversion in photovoltaic devices, and further relates to operation at high optical power and the resulting electrical power in photovoltaic devices.

### BACKGROUND OF THE INVENTION

Photovoltaic (PV) cells are semiconductor devices that convert photons of light (also known as photonic power, optical power, or light power) into electricity. The conversion utilizes the photovoltaic effect, which is generation of charge carriers (electrons and holes) in a light-absorbing material and separation of the charge carriers to conductive contacts that will transmit the electricity.

Groups of PV cells can be configured into modules and arrays, which can be used to charge batteries, operate motors, and to power any number of electrical loads. PV systems can be designed to provide direct current (DC) and/or alternating current (AC) power service, can operate interconnected with or independent of a utility grid, and can be connected with other energy sources and energy storage systems. For example, H₂ is an energy carrier that can be generated by splitting water through electrolysis, using electricity derived directly from a PV power system.

PV power systems can be classified according to their functional and operational requirements, component configurations, and type of connection to other power sources and electrical loads. The two principal classifications are grid-connected and stand-alone systems. Grid-connected PV systems are designed to operate in parallel with and interconnected with the electric utility grid. An inverter converts the DC power produced by the PV array into AC power consistent with the voltage and power quality requirements of the utility grid, and automatically stops supplying power to the grid when the PV system is not energized. Stand-alone PV systems are designed to operate independent of the electric utility grid, and are generally designed and sized to supply certain DC and/or AC electrical loads. One type of stand-alone PV system is a direct-coupled system, wherein the DC output of a PV module or array is directly connected to a DC load.

PV cells are connected electrically in series and/or parallel circuits to produce higher voltages, currents and power levels. PV modules consist of PV cell circuits sealed in an environmentally protective laminate, and are the fundamental building blocks of PV systems. PV panels include one or more PV modules assembled as a pre-wired, field-installable unit. A PV array is a complete power-generating unit, consisting of any number of PV modules and panels.

PV systems have a number of unique advantages over conventional power-generating technologies. PV systems have no moving parts, are modular, easily expandable, and sometimes transportable. Operating PV systems do not generate acoustic noise or pollution. In general, PV systems that are well designed and properly installed require minimal maintenance and have long service lifetimes. According to the Solar Energy Industries Association, the global photovoltaic market was worth $15 billion in 2005 and growing at a 30% annual rate (Chemical & Engineering News, Dec. 18, 2006).

Photonic power delivery that utilizes sunlight (solar light) has many advantages, including a “free” fuel source. Solar light also has certain disadvantages, including a broad spectrum of wavelengths that can lead to limited efficiencies, and the lack of availability at night. An alternative is to generate artificial light, from a laser or other source, transmit it through space or through a material such as an optical fiber, and then convert it into electricity using the photovoltaic effect.

The use of lasers to transmit power to PV arrays was proposed by Backus in 1972 (C. E. Backus, “Laser Activation of Solar Cells,” Proceedings of the 9th IEEE Photovoltaic Specialists Conference, Silver Spring, Md., May 1972, pp. 61-65). PV cells are generally more efficient under monochromatic illumination than under the wide spectral range of solar illumination (P. A. Iles, “Non-Solar Photovoltaic Cells,” Proceedings of the 21st IEEE Photovoltaic Specialists Conference, Vol. 1, Kissimimee, Fla., May 1990, pp. 420-425; L. C. Olsen et al., “High-Efficiency Monochromatic GaAs Solar Cells,” Proceedings of the 22nd IEEE Photovoltaic Specialists Conference, Vol. 2, Las Vegas, Nev., October 1991, pp. 419-423).

Laser power can be transmitted to PV cells and arrays through optical fibers, which guide photons along the length of the fibers, typically by total internal reflection but also sometimes by other means which may include, but are not limited to, photonic bandgap structures. It is widely recognized that optical fibers present a number of advantages compared to traditional electrical-power transport via copper cable. Chief advantages of optical fibers include the small size and weight of the fibers, compared to thick and heavy copper wires. Other advantages include the elimination of noise pickup, the elimination of high-voltage insulation, and generally safer electricity delivery.

Important uses of optical-fiber laser-power delivery include sensors in environments where electrical transmission is difficult or impossible. As just one commercial example, the electric-power industry has significantly shifted to photonic power for measurements of direct current at the high voltages used for long-distance electric-power transmission. Previously, these measurements had required large and expensive transformers filled with oil or gas to isolate the sensor from ground potential. Fiber power delivery is simpler, easier to install, immune to lightning strikes and electromagnetic interference, and avoids transformer hazards such as oil spills and explosions.

Flood-illuminated laser and solar PV devices are known in the art. In such devices, active PV cells are illuminated, relatively uniformly, by an incoming beam of photons. Crystalline silicon and gallium arsenide PV cells typically employ an array of metal wires or lines covering a portion of the cell's front surface to extract charge carriers from the doped surface layer. Because illumination of the metal occurs, some of the incident light is lost to reflection and absorption by the metal contact. Flood-illuminated PV devices typically require thin-wire leads in order not to obscure the light from impinging on the active PV area. However, back-surface wires are sometimes also employed.

Since the metal covers only a small area fraction of the surface of devices known in the art, photo-generated charge carriers must travel laterally inside the doped surface layer to reach the nearest metal line. The lateral current in the surface layer creates a non-uniform surface potential and can lead to significant ohmic losses due to the relatively low conductivity of the surface layer. While ohmic losses can be reduced by increasing the thickness and doping density of the emitter layer, a thick, heavily doped emitter layer is undesirable, since large dopant concentrations can result in reduced carrier lifetimes and other problems. Major problems associated with known devices can include joule heating due to unconverted optical power, ohmic loss (resistive heating) due to high current, and current shunting, which can lead to thermal runaway in the active PV material. All of these problems decrease the device efficiency.

The efficiency of the photon-to-electron power conversion is a very important design and operational consideration. Higher-efficiency devices result in lower levels of waste heat being left in the device, minimizing cooling requirements and maximizing useful lifetime and useful electricity generation. Reasonable device efficiencies for specific conversion wavelengths have been shown. For example, the art currently teaches about 40% efficiency for GaAs power converters optimized for 810-nm lasers (Spectrolab Inc.). An efficiency of about 40%, however, is not regarded as sufficient to handle high-watt laser power, due to problems such as joule heating, ohmic heating, and localized current shunting.

There is a need in the art to increase the power-conversion efficiency of laser-illuminated as well as solar-illuminated photovoltaic devices. A novel device design and method of operation are necessary to reduce or eliminate the significant factors leading to low efficiencies. What is specifically needed, therefore, is a commercially practical system that at least reduces joule heating, ohmic heating, and current shunting, while increasing the ability to remove any waste heat that is generated.

### SUMMARY OF THE INVENTION

The present invention comprises a method and apparatus to increase the efficiency of photovoltaic conversion of light into electrical power.

Some embodiments of the invention provide for a photovoltaic device for converting a beam of photons into electrical energy, said device comprising (i) a means for spatially separating the beam into a plurality of beamlets, (ii) a plurality of active photovoltaic cells, and (iii) an electrically conductive contact layer surrounding the active photovoltaic cells.

In preferred embodiments, the active photovoltaic cells are spatially separated within the contact layer to substantially match the pattern caused by the means for spatially separating the beam into a plurality of beamlets. The means for spatially separating the beam into a plurality of beamlets is preferably (but not necessarily) selected from the group consisting of a microlens array, a spatial light modulator array, a grating, and a fiber coupler/splitter. In a particular embodiment, a microlens array characterized by an essentially hexagonal pattern can be utilized.

In some embodiments, the active PV cells consist essentially of common semiconductor materials such as gallium arsenide (GaAs) or silicon (Si). In certain embodiments, various other elements are included in the active PV cells. For example, the active PV cells can include indium (InₓGa₁₋ₓAs, wherein x is, for example, selected from about 0.01 to about 0.25). One composition that can be employed in some embodiments is In_{0.12}Ga_{0.88}As semiconductor grown on GaAs substrate, which is optimized for laser light at a wavelength of about 975 nm. Other semiconductor materials can be utilized as the active PV material, as is well-known in the art.

The photovoltaic device comprises a contact layer surrounding the active photovoltaic cells. The contact layer preferably comprises one or more metals, such as those selected from the group consisting of gold, silver, aluminum, copper, iron, nickel, and zinc. One especially preferred metal is gold, or an alloy consisting essentially of gold. The contact layer surrounding the active photovoltaic cells can, in other embodiments, comprise one or more transparent conducting oxides, such as for example materials selected from the group consisting of tin oxide, zinc oxide, and indium oxide. In general, the contact layer is connected to a means for transmitting the electrical energy that is generated.

Although the invention is not limited to any particular length scale or dimension, in preferred devices the average thickness of the contact layer is from about 0.1 μm to about 5 μm. The active photovoltaic cells are generally characterized by an average diameter from about 0.1 mm to about 10 mm. Additionally, the average distance between the edges of individual active photovoltaic cells is generally from about 0.01 mm to about 10 mm, although the distance between PV cells is not constrained to this range. In general, the ratio of area of active photovoltaic cells to total area of the contact layer is less than about 0.8, preferably less than about 0.5.

In some embodiments of the device described herein, the active photovoltaic cells typically comprise multiple junctions, such as 2, 3, 4, 5, or more junctions. Preferably, when a multi junction device is desired, at least 3 junctions are employed as is known in the art. However, multi-band PV technologies offer another method for multi-spectral absorption.

The present invention also teaches a method of converting a beam of photons into electrical energy. In preferred embodiments, the method spatially separates a beam of photons into a plurality of beamlets at a first location, wherein the separation is characterized by a first array pattern; and registers the beamlets at a second location at least partially incident to the beamlets, the second location comprising active photovoltaic cells which are characterized by a second array pattern, wherein the first array pattern substantially matches the second array pattern. Preferred methods further provide an electrically conductive contact layer surrounding the active photovoltaic cells.

The beam of photons can be a laser beam delivered in open space, through optical fibers, or by any other means; the beam of photons can also comprise solar light. In some embodiments of the method of the invention, the photon beam is characterized by a wavelength from about 800 nm to about 1100 nm.

In some embodiments, each individual beamlet is effectively focused onto an area that is about the same as the area of each corresponding active photovoltaic cell. In other embodiments, each individual beamlet is effectively focused onto an area that is less than the area of each corresponding active photovoltaic cell. It is especially preferable, although not necessary, for the active photovoltaic cells to be illuminated by the plurality of beamlets uniformly with little or no shadowing of the beam or beamlets.

Preferred methods are conducted at an operating temperature between about 15° C. and about 45° C., although it is possible to use a temperature outside this range.

It will be appreciated by a skilled artisan that high device efficiencies are possible by practicing the methods taught herein. In preferred embodiments, the efficiency of energy conversion is at least about 40%, more preferably at least about 50%, and most preferably at least about 60%.

### BRIEF DESCRIPTION OF THE DRAWINGS

FIG. 1 illustrates one embodiment of the device of the invention, illustrating substantial matching of a plurality of beamlets and a plurality of PV cells.

FIG. 2 illustrates a composite view of one embodiment of the invention comprising a laser beam, a microlens array, and active PV substrate.

FIG. 3 depicts an illustrative embodiment of a system architecture for converting laser light into electrical power at a plurality of PV islands.

### DETAILED DESCRIPTION OF EMBODIMENTS OF THE INVENTION

The apparatus and methods of the present invention will now be described in detail by reference to various non-limiting embodiments of the invention.

Unless otherwise indicated, all numbers expressing dimensions, compositions, efficiencies, and so forth used in the specification and claims are to be understood as being modified in all instances by the term “about.” Without limiting the application of the doctrine of equivalents to the scope of the claims, each numerical parameter should at least be construed in light of the number of reported significant digits and by applying ordinary rounding techniques.

In one aspect of the present invention, a method and apparatus are provided to increase the efficiency of photovoltaic (PV) power conversion of lasers, delivered via optical fiber, into electrical power. A “laser” (from the acronym of Light Amplification by Stimulated Emission of Radiation) is an optical source that emits photons in a coherent beam. Throughout this description, “beam” is meant to include any source of photons, including laser or solar light. An “optical fiber” is typically a glass or plastic fiber designed to guide light along its length typically by total internal reflection but also sometimes by other means which may include, but are not limited to, photonic bandgap structures

In another aspect of the present invention, a method and apparatus are provided to increase the efficiency of PV power conversion of solar light into electrical power.

In yet another aspect of the present invention, a method and apparatus are provided to increase the efficiency of PV power conversion of laser beams, delivered through space, into electrical power.

Preferred embodiments increase the efficiency of PV power conversion of any source of a beam of photons by spatially dividing the beams into a plurality of individual beamlets, each beamlet focusing on an active PV region. A “beamlet” is itself also a source of photons and is not limited to any certain properties (such as wavelength or phase), or property changes, relative to the incident beam of photons. “Beamlet” only implies derivation from a beam of light, the light being spatially divided in some manner and focused into at least two beamlets.

The preferred architecture of the apparatus of the invention comprises spatially separated PV cells, also called PV islands or PV regions, to match the pattern of the spatially separated plurality of beamlets. Power conversion preferably occurs at each active PV cell impinged by individual beamlets. By matching the patterns of the beamlets and PV cells, the net illuminating area of the plurality of beamlets is less than the illuminating area of the beam that would occur without division into beamlets. The active PV area can therefore be lower than is typical. Also, shadowing by the metal layer is avoided by matching the patterns of the beamlets and PV cells. In the absence of shadowing, very little or no light is lost, meaning substantially all of the light is available for power conversion.

The active PV area can be decreased by spacing the individual PV cells relatively far apart, as further discussed below. Traditional flood-illuminated PV devices require that the active PV area is large and that the area covered by the metal wires is small. In contrast, by decreasing the active PV area according to the description herein, the area as well as the thickness of the metallization layer can be much larger. This increase in metallic volume directly results in a significant reduction in ohmic losses. As is known, ohmic losses contribute to lower PV cell efficiencies. Therefore, the overall PV efficiency can be increased tremendously, compared to a device that does not split the photon source into beamlets and match the plurality of beamlets with a plurality of PV cells. Efficiency considerations are further discussed below.

One design consideration associated with the present invention relates to the material for the active PV region. Generally, the selection of specific PV material is not regarded as critical, i.e. the present invention allows for efficiency increases for any PV material. As is well-known in the art, however, material properties greatly impact PV performance, and such performance will vary according to the methods employed herein as well. Selection of PV material is typically done in conjunction with selection of the wavelength or wavelengths of the source of photons to be converted into energy.

More specifically, the selection of PV material can be driven by the peak-response wavelength, i.e. the wavelength of the beamlets that corresponds to the maximum conversion efficiency for the material. Alternately, a material can be selected, and a curve of conversion efficiency versus wavelength can be prepared by routine experimentation. Such experimentation can be conducted at, for example, 25° C. and 1 W/cm² or any other conditions of interest, and can result in establishing a peak-response wavelength for a given material. This information can then be used in the design of one or more laser sources for the system.

In some embodiments of the photovoltaic device of the invention, the active PV cells consist essentially of common semiconductor materials such as gallium arsenide (GaAs) or silicon (Si). In certain embodiments, various other elements are included in the material for the active PV cells. For example, the active PV cells can include indium. When indium is included with gallium arsenide, the generic composition is InₓGa₁₋ₓAs. Indium is known for its superior electron velocity with respect to both silicon and gallium arsenide. The indium content (the value of x) determines the two-dimensional charge carrier density and can generally be any value from x=0 to x=1; often x is less than about 0.25. One specific composition that can be employed in some preferred embodiments is In_{0.12}Ga_{0.88}As (x=0.12) semiconductor grown on GaAs substrate, which is optimized for laser light at a wavelength of about 975 nm.

Other known semiconductor materials can be utilized as the active PV material, such as one or more of silicon carbide (SiC), silicon germanide (SiGe), aluminum antimonide (AlSb), aluminum arsenide (AlAs), aluminum nitride (AlN), aluminum phosphide (AlP), boron nitride (BN), boron arsenide (BAs), gallium antimonide (GaSb), gallium nitride (GaN), gallium phosphide (GaP), indium antimonide (InSb), indium arsenide (InAs), indium nitride (InN), indium phosphide (InP), aluminum gallium arsenide (AlGaAs), indium gallium arsenide (InGaAs), aluminum indium arsenide (AlInAs), aluminum indium antimonide (AlInSb), gallium arsenide nitride (GaAsN), gallium arsenide phosphide (GaAsP), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), aluminum indium arsenide phosphide (AlInAsP), aluminum gallium arsenide nitride (AlGaAsN), indium gallium arsenide nitride (InGaAsN), indium aluminum arsenide nitride (InAlAsN), gallium indium nitride arsenide antimonide (GaInNAsSb), cadmium selenide (CdSe), cadmium sulfide (CdS), cadmium telluride (CdTe), zinc oxide (ZnO), zinc selenide (ZnSe), zinc sulfide (ZnS), zinc telluride (ZnTe), cadmium zinc telluride (CdZnTe), mercury cadmium telluride (HgCdTe), mercury zinc telluride (HgZnTe), mercury zinc selenide (HgZnSe), cuprous chloride (CuCl), lead selenide (PbSe), lead sulfide (PbS), lead telluride (PbTe), tin sulfide (SnS), tin telluride (SnTe), lead tin telluride (PbSnTe), thallium tin telluride (Tl₂SnTe₅), thallium germanium telluride (Tl₂GeTe₅), bismuth telluride (Bi₂Te₃), cadmium phosphide (Cd₃P₂), cadmium arsenide (Cd₃As₂), cadmium antimonide (Cd₃Sb₂), zinc phosphide (Zn₃P₂), zinc arsenide (Zn₃As₂), zinc antimonide (Zn₃Sb₂), lead(II) iodide (PbI₂), molybdenum disulfide (MoS₂), gallium selenide (GaSe), tin sulfide (SnS), bismuth sulfide (Bi₂S₃), copper indium gallium selenide (CuInGaSe), platinum silicide (PtSi), bismuth(III) iodide (BiI₃), Mercury(II) iodide (HgI₂), thallium(I) bromide (TlBr), germanium (Ge), diamond (C), pentacene, anthracene, rubrene, poly(3-hexylthiophene), poly(p-phenylene vinylene), and polyacetylene.

Minor composition differences across PV cells are contemplated. For example, during fabrication, minor variations in PV-cell compositions can and do occur, including variations in impurity level as well as overall stoichiometry. In principle, different PV cells could intentionally be made from different materials, although such profiling may not be practical. One reason to vary the PV material across cells is to match variations in wavelengths of incoming beamlets, if they are not all the same.

As discussed above, the choice of material for the active PV cells of the invention will preferably depend on the known or desired wavelength or wavelengths of the light source. In embodiments using laser light, wavelengths can generally be in the range of about 200 nm to about 1500 nm or higher, including wavelengths within the ultraviolet (UV), visible, and infrared (IR) regions of the electromagnetic spectrum. In preferred embodiments, wavelengths of the source beam are from the near-IR region, about 700 nm to about 1300 nm. In more-preferred embodiments, wavelengths of the source beam are within a range of about 800 nm to about 1100 nm. One exemplary embodiment uses a 975-nm laser wavelength in conjunction with active PV cells comprising In_{0.12}Ga_{0.88}As.

Absolutely monochromatic light with only a single wavelength is an unattainable idealization, although laser light can approach a monochromatic wavelength. Throughout this specification, reference to a specific wavelength is meant to include a small band of wavelengths around the specific wavelength, such band being at least about 1 nm, up to about 10 nm, or higher, depending on the laser source. For the purpose of the description of embodiments herein, by “975-nm laser wavelength” is meant a beam of photons, or a plurality of beamlets, that are characterized by wavelengths from about 965 nm to about 985 nm.

As is known, solar light is not monochromatic. The sun emits light primarily in the visible spectrum (about 400-700 nm), but it also emits photons at other wavelengths, starting at about 200 nm and exceeding 2000 nm. For embodiments of the invention using solar light, one or more PV materials can be selected from the list of semiconductor materials recited above.

The preferred device of the invention comprises a metal contact layer, instead of wire bonds, to reduce ohmic losses. The metal contact layer is preferably from about 0.1 μm to about 5 μm or more. In preferred embodiments, the contact layer surrounding active PV cells comprises one or more metals selected from the group consisting of gold, silver, aluminum, copper, iron, nickel, and zinc. In especially preferred embodiments, the contact layer consists essentially of gold. Other electrically conductive materials can be used as well, and the specific choice of metal contact layer will not defeat the purpose of the invention.

Some embodiments utilize transparent conducting oxides. The dual function of a transparent conducting oxide allows light to pass through to the active PV material, and also serves as an ohmic contact to transport photogenerated charge carriers away from that light-absorbing PV material. Transparent conducting oxides, when employed, are preferably (but not necessarily) selected from the group consisting of tin oxide, zinc oxide, and indium oxide. Multicomponent metal oxides consisting of combinations of tin oxide, zinc oxide, and indium oxide can also be used.

Another design consideration for the methods and devices of the invention, along with material selection discussed above, is the means for generating a plurality of beamlets from an illuminating beam of light. In general, there are several ways known in the art to divide a beam into beamlets. Examples include a microlens array, a fiber-based coupler/splitter, and a plurality of beam splitters.

Microlens arrays (also referred to as microlenticular arrays or lenslet arrays) are well-known in industry and are widely commercially available (e.g., SUSS MicroOptics SA, Switzerland; MEMS Optical, United States). Microlens arrays can be fabricated with arbitrary lens profiles and array symmetries. They can be refractive or diffractive, can have aspheric or anamorphic profiles, and can be characterized by square, rectangular, hexagonal, random, or other distributions. Preferred embodiments of the invention use microlens arrays that are hexagonally distributed. Various materials can be used for the microlens array, such as polymer replicated on glass substrate, polycarbonate, polydimethylsiloxane, acrylic, fused silica, silicon, and calcium fluoride.

Fiber-based coupler/splitters can be used to generate a plurality of beamlets from a light source delivered through optical fibers. A fiber splitter divides a beam of light, such as from a laser, into a plurality of separate beamlets. A fiber coupler is simply a splitter in reverse, and the term “coupler/splitter” is often used to denote a common device that can be operated to either split or couple beams of light.

Various types of beam splitters are also known in the art. Regular beam splitters are used to split or combine laser beams. Polarization beam splitters are used to split or combine two perpendicular polarization laser beams. Generally, a beam splitter splits a source of photons into two beamlets, so a plurality of beam splitters would be necessary to generate a number of beamlets in excess of two, which is preferable. A plurality of beam splitters can be realized in, for example, a beam splitter grating or spot-array generation grating.

In addition to various means of separating a single beam of light into a plurality of beamlets, it is also contemplated that a plurality of light sources could be generated directly into a desired pattern. These embodiments could employ, for example, diode arrays, also known as diode bars or a plurality of single emitters.

Some embodiments can further employ a beamlet manipulator or filter to attenuate one or more undesired beamlets (for whatever reason) and pass the desired beamlets on to the PV cells. The filter could, for instance, be an opaque material having a plurality of apertures aligning with the plurality of desired beamlets, with one or more undesired beamlets not aligned with the plurality of apertures.

In preferred embodiments, the beamlet-creating optics are designed to provide a substantially known illumination profile across the area containing the active PV regions. Preferably, the illumination profile is uniform (or essentially uniform), but it need not be. Furthermore, the cooling of the active region should be engineered to match the known heating profile. When the illumination profile is essentially uniform, the cooling profile of the active region is preferably also essentially uniform.

The overall distribution of the plurality of beamlets needs to be distinguished from the intensity distribution of a distinct beamlet. The overall distribution is preferably substantially uniform, as described above. In some embodiments, the intensity distribution of individual beamlets impinging on PV cells is substantially Gaussian, with the peak of intensity at or near the center of the incident PV cell.

Beamlets do not typically have a uniform profile across the entire area of their output. Beamlet shapers can be included in, or added to, the means for generating beamlets, wherein the beamlet shapers convert a Gaussian beamlet intensity profile to a uniform “top hat” shape with sharp edges. Such beam or beamlet shapers are available commercially (e.g., by MEMS Optical), and high-performance beam shapers are known to provide uniformity within about 2%. Uniform beamlet profiles can also be obtained, in principle, using complex two-dimensional arrays with a plurality lenses.

In preferred devices and methods of the invention, there is a 1:1 ratio between the number of separate beamlets generated and the number of separate PV cells. It will be appreciated by a skilled artisan that variations are possible in the ratio, either due to design or in practice. For example, a design flaw within the means of dividing the beam into beamlets could cause a “missing” beamlet. Or, one or more PV cells may be missing or inactive for a variety of reasons, thus causing an ineffective beamlet.

In preferred devices and methods of the invention, each beamlet is effective for photovoltaic conversion at its corresponding PV cell, meaning that the beamlet's intensity profile is virtually fully contained, at the plane of impingement, within the area of the single PV cell or pixel. In the case that the beamlet distribution is Gaussian, statistical considerations imply that a very small portion of a beamlet can fail to impinge its corresponding PV cell. “Matching” of patterns between beamlets and PV cells, for the purpose of the present invention, is meant to encompass this situation.

Regardless of individual intensity profiles, “substantial matching” of the array patterns of beamlets and PV cells means that at least 50%, preferably at least 75%, more preferably at least 90%, still more preferably at least 95%, and most preferably at least 99% of the light contained in an average beamlet is focused and registered at an average PV cell of the devices and methods of the invention. It will be recognized that an average of less than 100% of light registered results in a loss of efficiency. Therefore, in preferred embodiments care is taken to ensure that the average percentage of beamlet light registered at PV cells is as high as possible.

If essentially all of the beamlet light is registered but the area of each PV cell is greater than the area of each impinging beamlet, then PV material is wasted. This situation can also lead to an efficiency loss. It is thus preferable that the areas of the beamlets, at impingement, be about the same as, or less than, the areas of corresponding PV cells. In preferred embodiments, the focal spot sizes (areas) of the beamlets are somewhat less than the areas of the PV pixels.

The geometry of the PV cells is flexible, but in preferred embodiments is circular. The average diameter of PV cells can vary as well, and in exemplary embodiments is from about 0.1 mm to about 10 mm, preferably from about 0.5 mm to about 2 mm. The distance between PV cells is governed by the array pattern of the PV cells, which substantially matches the array pattern of the impinging beamlets. In exemplary embodiments, the average distance between the edges of individual PV cells is from about 0.01 mm to about 10 mm. In preferred embodiments, the average distance between the edges of individual PV cells is at least about half of the average cell diameter, more preferably at least about equal to said average cell diameter.

Larger distances between active PV cells are preferred, because the implied higher fraction of metal means that ohmic losses can be minimized and that thermal runaway and current shunting can be avoided. Another way to characterize these dimensions is by the ratio of area of active photovoltaic cells to total area of the layer impinged by the beamlets. This ratio is preferably less than about 0.8, and more preferably less than about 0.5.

Various embodiments of the invention can be further described according to the figures contained herein. The figures are understood to provide representative illustration of the invention and are not limiting in their content. It will be understood by one of ordinary skill in the art that the scope of the invention extends beyond the specific embodiments depicted. This invention also incorporates routine experimentation and optimization of the methods, apparatus, and systems described herein.

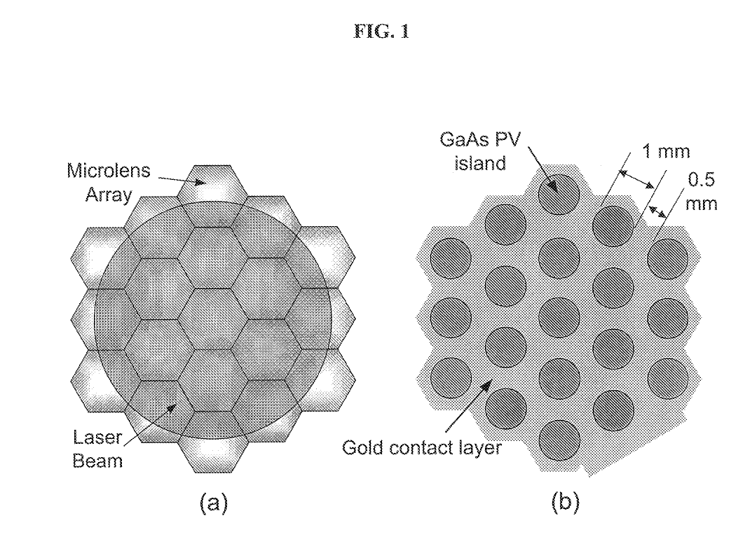

FIG. 1 illustrates one embodiment comprising an array of active GaAs PV islands in a sea of gold for focused laser illumination. The PV islands are arranged hexagonally, to match the hexagonal pattern of the microlens array. FIG. 1(a) illustrates the illumination of a circularly symmetric laser beam onto the hexagonal microlens array; FIG. 1(b) illustrates the substantially matching hexagonal arrangement of active GaAs PV islands. The thick and wide gold metallization layer serves to reduce the ohmic losses and to help spread the heat generated in the PV active regions.

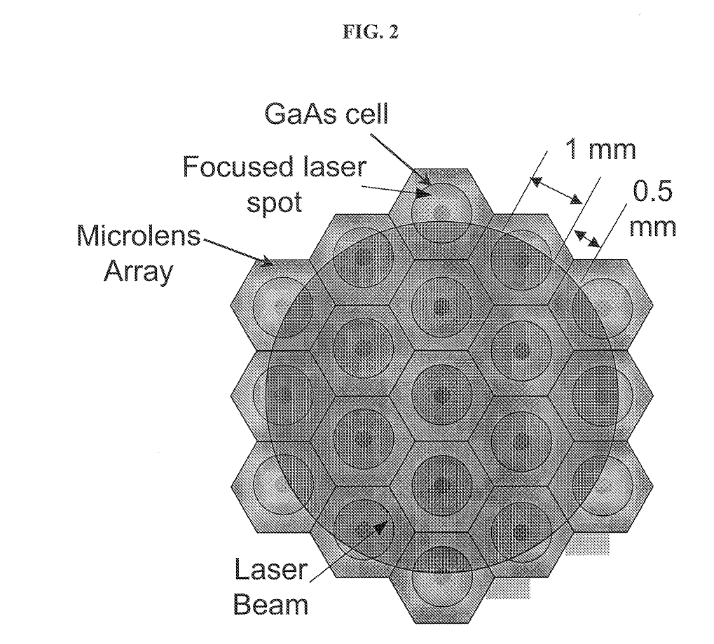

FIG. 2 illustrates a composite view of one embodiment comprising a laser beam, a microlens array, and active PV substrate with individual beamlet foci, shown by darkly shaded circles within the circular GaAs islands. The length scale of the foci is less than the length scale of the PV islands, which ensures that substantially no laser photons impinge onto any surface outside of the PV islands.

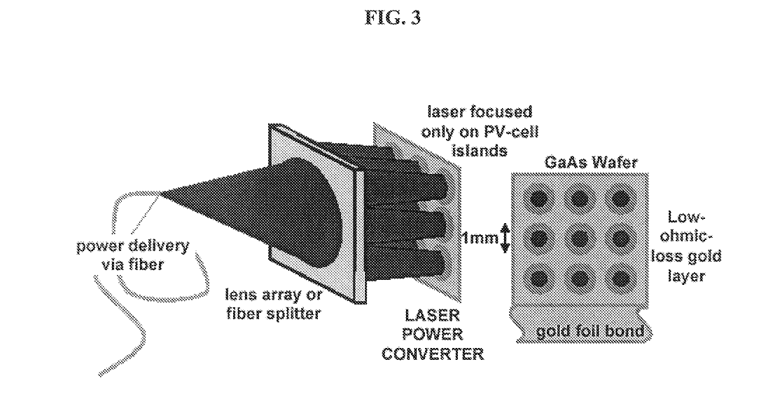

FIG. 3 depicts an illustrative embodiment of a system architecture for converting fiber-delivered optical power into electrical power at a plurality of PV islands. In FIG. 3, a microlens array as well as a GaAs wafer are both characterized by a square-pattern array, wherein the microlens and wafer are configured in a manner such that laser beamlets selectively contact the GaAs PV islands, rather than the gold metal layer. In this particular embodiment, the PV islands are on the order of 1 mm in diameter; the PV regions are electrically contacted by a 0.5-μm thick gold layer. A gold-foil bond at the edge of the device connects the device to a power supply to deliver electricity to one or more users.

Conversion efficiency is an important device parameter, as discussed above. By “conversion efficiency” is meant the electrical energy that is generated by the photovoltaic effect and conducted away for effective use, divided by the optical energy embodied by the incoming photons. The devices and methods of the invention can increase the photon-to-electron conversion efficiency by addressing major known problems associated with PV cells, including joule heating due to unconverted optical power, ohmic loss (resistive heating) due to high current, and current shunting, which can lead to thermal runaway in the active material. In preferred embodiments, the heat produced in the islands is well-managed as a result of the relatively large dimensions of the metallization layer.

In general, the systems, devices, and methods of the present invention allow increased power-conversion efficiencies, up to about the fundamental limits for a given material, device architecture, beamlet wavelength, and other operating and environmental conditions. The theoretical maximum efficiency of power conversion is the quantum limit, which can be calculated or estimated for a given material based on entropy arguments. This quantum limit varies but is typically between approximately 70% and 90%.

In preferred methods of the invention, the efficiency of energy conversion is at least about 40%, more preferably at least about 50%, and most preferably at least about 60% or more. In terms of an approach to the specific quantum limit of a particular device, in preferred embodiments the efficiency of energy conversion is at least about 0.5 times the quantum limit, more preferably at least about 0.6 times the quantum limit, still more preferably at least about 0.7 times the quantum limit, yet more preferably at least about 0.8 times the quantum limit, and most preferably at least about 0.9 times the quantum limit, up to an efficiency that is about the quantum limit governing the conversion of photons to electricity at the PV cells of the invention.

Operating temperature is another factor that will influence conversion efficiency. PV-cell operating temperature puts a limit on the highest intensities possible. The efficiency of a PV cell will generally decrease with operating temperature. Efficiencies are least sensitive to temperature for wide-bandgap (short wavelength) cells such as GaAs. The sensitivity to temperature increases for narrow-bandgap (long wavelength) cells such as GaSb. In preferred embodiments of the device and apparatus of the invention, the operating temperature is between about 15° C. and about 45° C.

Certain additional efficiency considerations can arise when solar light is to be utilized as a light source, primarily due to the range of wavelengths in solar light. Generally, the means of generating a plurality of beamlets, the matching of beamlet and PV-cell array patterns, the dimensions of the PV cells and contact layer, the selection of PV material, and other design criteria are subject to routine experimentation and optimization by a person of ordinary skill in the art.

To further increase the device efficiency when solar light (or any other source of light containing a plurality of wavelengths) is used, multiple junctions can be employed in the PV cells. Individual multi junction PV cells are made of layers, wherein each layer captures part of the light passing through the cell, thereby allowing the cell to absorb more energy from the sun's light (or other light comprising a plurality of wavelengths).

Multi junction PV cells can achieve a higher efficiency by capturing more of the solar spectrum. Namely, a plurality of layers within a PV cell have a plurality of different peak-response wavelengths that can be similar to a plurality of wavelengths in the incoming light or beamlets. In preferred embodiments employing multi junction PV cells, at least four junctions are used. Also, as is known, multi junction PV cells can reduce the overall current (and therefore reduce waste heat) by increasing the operating voltage. Also, the use of multi-band PV devices is another way to achieve higher efficiency in the case of solar or broadband illumination.

Embodiments of the invention can be used for virtually any application requiring the efficient power conversion of laser power, or solar power, into prime electrical power. Certain applications can require that the power converter handle 1 kW of laser power with an area of a few square centimeters, coupled with the need to remove waste heat. These applications enjoy the advantages that result from the devices and methods of the invention.

Specific methods of using the present invention include remote power applications that require a small reliable power source; power for individual buildings, remote homes, and commercial facilities where there is no connection to the utility grid; remote area lighting for parking areas, jogging trails, and walkways; water pumping; data collection; radio and microwave repeater stations; and warning lights for offshore structures.

In this detailed description, reference has been made to multiple embodiments and to the accompanying drawings in which is shown by way of illustration specific exemplary embodiments in which the invention may be practiced. These embodiments are described in sufficient detail to enable those skilled in the art to practice the invention, and it is to be understood that modifications to the various disclosed embodiments may be made by a skilled artisan. Other embodiments that do not provide all of the features and advantages set forth herein may be utilized, without departing from the spirit and scope of the present invention. Such modifications and variations are considered to be within the scope of the invention defined by the appended claims.

1. A photovoltaic device for converting a beam of photons into electrical energy, said device comprising:
(a) a means for spatially separating the beam into a plurality of beamlets;
(b) a plurality of active photovoltaic cells; and
(c) an electrically conductive contact layer surrounding the active photovoltaic cells.

2. The device of claim 1, wherein said active photovoltaic cells are spatially separated within said contact layer to substantially match the pattern caused by said means for spatially separating the beam into a plurality of beamlets.

3. The device of claim 1, wherein said means for spatially separating said beam into said plurality of beamlets is selected from the group consisting of a microlens array, a grating, and a fiber coupler/splitter.

4. The device of claim 3, wherein said means for spatially separating said beam into beamlets is a microlens array.

5. The device of claim 4, wherein said microlens array is characterized by an essentially hexagonal pattern.

6. The device of claim 1, wherein at least one of said active photovoltaic cells comprises GaAs.

7. The device of claim 1, wherein at least one of said active photovoltaic cells comprises InₓGa₁₋ₓAs, wherein x is from about 0.01 to about 0.25.

8. The device of claim 7, wherein at least one of said active photovoltaic cells comprises In_{0.12}Ga_{0.88}As.

9. The device of claim 1, wherein at least one of said active photovoltaic cells comprises silicon.

10. The device of claim 1, wherein said contact layer surrounding said active photovoltaic cells comprises one or more metals.

11. The device of claim 10, wherein said contact layer surrounding said active photovoltaic cells comprises one or more metals selected from the group consisting of gold, silver, aluminum, copper, iron, nickel, and zinc.

12. The device of claim 11, wherein said contact layer surrounding said active photovoltaic cells consists essentially of gold.

13. The device of claim 1, wherein said contact layer surrounding said active photovoltaic cells comprises one or more transparent conducting oxides.

14. The device of claim 13, wherein said contact layer surrounding said active photovoltaic cells comprises one or more transparent conducting oxides selected from the group consisting of tin oxide, zinc oxide, and indium oxide.

15. The device of claim 1, wherein the average thickness of said contact layer is from about 0.1 μm to about 5 μm.

16. The device of claim 1, wherein said active photovoltaic cells are characterized by an average diameter from about 0.1 mm to about 10 mm.

17. The device of claim 16, wherein said active photovoltaic cells are characterized by an average diameter from about 0.5 mm to about 2 mm.

18. The device of claim 1, wherein the average distance between the edges of individual active photovoltaic cells is from about 0.01 mm to about 10 mm.

19. The device of claim 16, wherein the average distance between the edges of individual active photovoltaic cells is at least about half of said average cell diameter.

20. The device of claim 19, wherein the average distance between the edges of individual active photovoltaic cells is at least about equal to said average cell diameter.

21. The device of claim 1, wherein the ratio of area of active photovoltaic cells to total area of the contact layer is less than about 0.8.

22. The device of claim 21, wherein the ratio of area of active photovoltaic cells to total area of the contact layer is less than about 0.5.

23. The device of claim 1, wherein said active photovoltaic cells comprise at least 2 junctions.

24. The device of claim 1, wherein said active photovoltaic cells comprise at least one multi-band junction.

25. The device of claim 1, further comprising a connection of said contact layer to a means for transmitting said electrical energy.

26. A method of converting a beam of photons into electrical energy, comprising:
(a) providing a beam of photons;
(b) spatially separating said beam into a plurality of beamlets at a first location, wherein the separation is characterized by a first array pattern;
(c) registering said beamlets at a second location at least partially incident to said beamlets, said second location comprising said active photovoltaic cells which are characterized by a second array pattern; and
(d) providing an electrically conductive contact layer surrounding the active photovoltaic cells,
wherein said first array pattern substantially matches said second array pattern.

27. The method of claim 26, wherein said beam in step (a) is a laser beam.

28. The method of claim 27, wherein step (a) is accomplished using optical fibers.

29. The method of claim 27, wherein the laser beam is characterized by at least one wavelength from about 800 nm to about 1100 nm.

30. The method of claim 26, wherein said beam in step (a) comprises photons contained in solar light.

31. The method of claim 26, wherein step (b) comprises using a microlens array.

32. The method of claim 26, wherein during registering of step (c), each individual beamlet is effectively focused onto an area that is about the same as the area of each corresponding active photovoltaic cell.

33. The method of claim 32, wherein during registering of step (c), each individual beamlet is effectively focused onto an area that is less than the area of each corresponding active photovoltaic cell.

34. The method of claim 26, wherein the operation temperature is between about 15° C. and about 45° C.

35. The method of claim 26, wherein said active photovoltaic cells are illuminated by said plurality of beamlets uniformly.

36. The method of claim 26, wherein during steps (b) and (c), no shadowing of the beam or beamlets occurs.

37. The method of claim 26, wherein the efficiency of energy conversion is at least about 40%.

38. The method of claim 37, wherein the efficiency of energy conversion is at least about 50%.
